(19) United States
(12) Patent Application Publication
(10) Pub. No.: US 2026/0209586 A1
(43) Pub. Date: Jul. 23, 2026

(54) COMPOUND FOR A TWO-PHASE IMMERSION COOLANT

(71) Applicant: Microsoft Technology Licensing, LLC, Redmond, WA (US)

(72) Inventors: Dennis Wai-Ching TOM, Redmond, WA (US); Alexis Woodward MILLS, Bellevue, WA (US); Alexandra EFIMOVSKAYA, Redmond, WA (US); Hongbin LIU, Redmond, WA (US); Nathan Andrew BAKER, Kennewick, WA (US); Chong SUN, Austin, TX (US); Yinuo YANG, Gainesville, FL (US); Kevin Khoa HOANG, Federal Way, WA (US)

(21) Appl. No.: 19/094,501

(22) Filed: Mar. 28, 2025

Related U.S. Application Data
(60) Provisional application No. 63/746,830, filed on Jan. 17, 2025.

(51) Int. Cl. C09K 5/04; H05K 7/20

(52) U.S. Cl. CPC C09K 5/04; H05K 7/203; H05K 7/20318

(57) ABSTRACT

Disclosed herein is the compound CCC═C(F)CF. The compound can be provided as a pure isomer of either the E-isomer or Z-isomer, or as a diastereomeric mixture of both isomers (i.e., an E/Z mixture). The boiling point and dielectric constant of the compound enable effective use of the compound as a coolant in a two-phase immersion cooling system. A two-phase immersion cooling system incorporating the compound as coolant can include: an immersion tank configured to contain the coolant and to contain a component capable of generating heat; and a condenser configured to receive vaporized coolant and to condense the vaporized coolant back to liquid form.

### CROSS-REFERENCE TO RELATED APPLICATIONS

This application claims the benefit of and priority to U.S. Provisional Patent Application No. 63/746,830, filed Jan. 17, 2025, the entirety of which is incorporated herein by reference.

### BACKGROUND

Two-phase immersion cooling is a method of thermal management with applications in industrial settings, data centers, and high-performance computing, for example. Two-phase immersion cooling utilizes the phase change properties of a coolant to promote dissipation of heat from associated equipment. In applications that involve cooling of electrical equipment, the coolant is a dielectric liquid to prevent damage to the electrical equipment.

The equipment to be cooled is submerged within the liquid coolant. As the equipment operates, the heat generated by the equipment is transferred to the liquid coolant, eventually bringing the liquid coolant to its boiling point. Boiling of the coolant enhances heat transfer due to the latent heat of vaporization (energy used during the liquid-to-vapor transition) of the coolant.

In contrast, single-phase immersion cooling involves submerging the equipment in a dielectric fluid that is formulated to remain in the liquid phase throughout the cooling cycle. Heat transfer in single-phase cooling relies solely on the coolant's heat capacity and thermal conduction/convection efficiency. That is, single-phase immersion cooling cannot make use of the latent heat of vaporization of the coolant.

Though two-phase immersion cooling offers the potential for multiple benefits such as improved heat transfer efficiencies, cooling capacity, and energy efficiency, several limitations remain. Two-phase immersion cooling requires specialized coolant compositions with specific boiling points that enable thermal control at an appropriate target temperature. Currently, two-phase immersion cooling systems generally utilize per- and polyfluoroalkyl substances (PFAS) as coolants. The use of PFAS, however, raises several environmental and health concerns. PFAS are long lasting compounds (often referred to as “forever chemicals”) that persistent in the environment. PFAS can accumulate in blood and organs of humans and animals, and such exposure can cause increased cholesterol levels, increased risk of certain cancers, endocrine system disruption, fertility issues, liver toxicity, and impaired kidney function, among other health concerns.

Accordingly, there remains a need for new solutions that can improve the feasibility of two-phase immersion cooling.

### SUMMARY

Disclosed herein is the compound CCC═C(F)CF. The compound has the two diastereomer forms shown below:

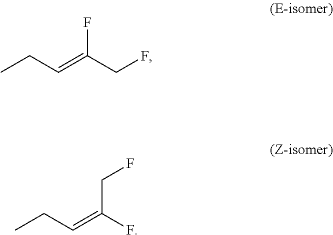

The compound can be provided as a pure isomer of either the E-isomer or Z-isomer, or as a diastereomeric mixture of both isomers (i.e., an E/Z mixture). The E/Z mixture can have any E:Z isomeric ratio, including a 9:1 ratio, 8:1 ratio, 7:1 ratio, 6:1 ratio, 5:1 ratio, 4:1 ratio, 3:1 ratio, 2:1 ratio, 1:1 ratio, 1:2 ratio, 1:3 ratio, 1:4 ratio, 1:5 ratio, 1:6 ratio, 1:7 ratio, 1:8 ratio, 1:9 ratio, or can have an E:Z isomeric ratio within a range that used any combination of the foregoing ratios as endpoints.

The boiling point and dielectric constant of the compound enable effective use of the compound as a coolant in a two-phase immersion cooling system. Further, the compound can be nontoxic, nonflammable, nonexplosive, and water inert, for example. Moreover, unlike conventional coolants used in two-phase immersion cooling systems, the disclosed compound is not a PFAS and can therefore be used with reduced environmental and health concerns as compared to PFAS coolants.

Also disclosed herein is a coolant composition for a two-phase immersion cooling system, the coolant comprising the compound CCC═C(F)CF. The coolant composition can be utilized in any two-phase immersion cooling system, including systems with open bath construction or sealed tank construction; systems with direct contact cooling or those that include one or more intermediate heat transfer layers; systems that use air-cooled and/or liquid-cooled condensers; systems that use condensers with coils and/or radiator fins; systems that integrate the condenser locally or that pipe coolant vapor to a remote condenser before returning condensed liquid coolant, and systems that combine any subset of the foregoing features.

Also disclosed herein is a two-phase immersion cooling system, the system comprising: a dielectric coolant; an immersion tank configured to contain the dielectric coolant and a component to be cooled; and a condenser configured to receive vaporized coolant and to condense the vaporized coolant back to liquid form, wherein the dielectric coolant comprises the compound CCC═C(F)CF.

Also disclosed herein is a method of using the compound CCC═C(F)CF as a coolant in a two-phase immersion cooling system. Such a system can be utilized to cool data centers, cryptocurrency mining operations, and/or high-performance or supercomputing systems, for example. The disclosed cooling system can be used in conjunction with computing operations associated with various functions/services such as artificial intelligence, machine learning, and big data analytics, for example. In computing operations, the enhanced cooling enabled by the disclosed two-phase immersion cooling system can minimize the need for traditional air conditioning or chilled water systems and/or can allow for higher server packing and more compact equipment arrangements. The disclosed cooling system can also have applications beyond computing operations, including for cooling electric vehicle batteries, electric grid and/or power supply electronics, aerospace equipment, telecommunications equipment, and industrial equipment, for example.

This summary is provided to introduce a selection of concepts in a simplified form that are further described below in the detailed description. This summary is not intended to identify key features or essential features of the claimed subject matter, nor is it intended to be used as an indication of the scope of the claimed subject matter.

### BRIEF DESCRIPTION OF THE DRAWINGS

Various objects, features, characteristics, and advantages of the invention will become apparent and more readily appreciated from the following description of the embodiments, taken in conjunction with the accompanying drawings and the appended claims, all of which form a part of this specification. In the Drawings, like reference numerals may be utilized to designate corresponding or similar parts in the various Figures, and the various elements depicted are not necessarily drawn to scale, wherein:

FIGS. 1A and 1B illustrate an example two-phase immersion cooling system with different configurations for dissipating heat to an external environment; and

FIG. 2 illustrates an example synthesis route for synthesizing the compound CCC═C(F)CF.

### DETAILED DESCRIPTION

### Introduction

Disclosed herein is the compound CCC═C(F)CF. The compound has the two diastereomer forms shown below:

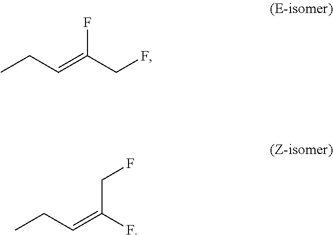

The compound can be provided as a pure isomer of either the E-isomer or Z-isomer, or as a diastereomeric mixture of both isomers (i.e., an E/Z mixture). The E/Z mixture can have any E:Z isomeric ratio, including a 9:1 ratio, 8:1 ratio, 7:1 ratio, 6:1 ratio, 5:1 ratio, 4:1 ratio, 3:1 ratio, 2:1 ratio, 1:1 ratio, 1:2 ratio, 1:3 ratio, 1:4 ratio, 1:5 ratio, 1:6 ratio, 1:7 ratio, 1:8 ratio, 1:9 ratio, or can have an E:Z isomeric ratio within a range that used any combination of the foregoing ratios as endpoints.

In accordance with the standard E/Z naming system, the E-isomer positions the two highest priority groups (the —CF and —CC groups) on opposite sides of the double bond, whereas the Z-isomer places them on the same side of the double bond.

### Dielectric Coolant

The compound CCC═C(F)CF has several properties that enable effective use of the compound as a coolant in a two-phase immersion cooling system. For example, the compound exhibits a dielectric constant (predicted value of 4.2) that is high enough for safe contact with electrical equipment.

The compound also has a boiling point (about 82 to 85° C. depending on isomer ratio) that is low enough to begin boiling and provide evaporative cooling before reaching equipment failure temperatures, yet high enough to minimize excessive vaporization of the coolant and/or evaporative losses of coolant over time. The boiling point of the compound is relatively high compared to some other conventional two-phase immersion coolants but is still within the tolerance range of many common applications and can be particularly beneficial in applications where such operating temperatures are acceptable or advantageous, such as in certain high-performance electronics, industrial systems, power supply/delivery systems, automotive applications (e.g., electric vehicles), and telecommunications systems.

Further, the compound is nontoxic, nonflammable, nonexplosive, and water inert. Moreover, unlike conventional coolants used in two-phase immersion cooling systems, the disclosed compound is not a PFAS and can therefore be used with reduced environmental and health concerns as compared to PFAS coolants.

### Cooling System

Also disclosed herein is a two-phase immersion cooling system, the system comprising: a dielectric coolant; an immersion tank configured to contain the dielectric coolant and to contain a component capable of generating heat; and a condenser configured to receive vaporized coolant and to condense the vaporized coolant back to liquid form, wherein the dielectric coolant comprises the compound CCC═C(F)CF. Advantageously, the cooling system can essentially or completely omit coolant compositions that are not the compound CCC═C(F)CF, such as PFAS.

The condenser can include, for example, a cooling loop and/or a set of thermal radiative elements (e.g., coils and/or radiator fins). The condenser can be associated with external components configured for dissipating heat to an environment external to the immersion tank (e.g., to the ambient environment outside of the building in which the immersion tank and equipment to be cooled are placed).

The component capable of generating heat can include any object or piece of equipment for which it is desirable to maintain at a controlled temperature (e.g., at a temperature at or below the boiling point of the coolant). Examples include motherboards, central processing units (CPUs), graphics processing units (GPUs), memory modules, solid-state drives (SSDs), application-specific integrated circuits (ASICs), switches, routers, network interface cards (NICs), power supply units (PSUs), power distribution units (PDUs), inverters, transformers, rectifiers, battery cells, battery management systems (BMS), radio equipment, radar electronics, microcontrollers, motors, actuators, and power amplifiers, for example.

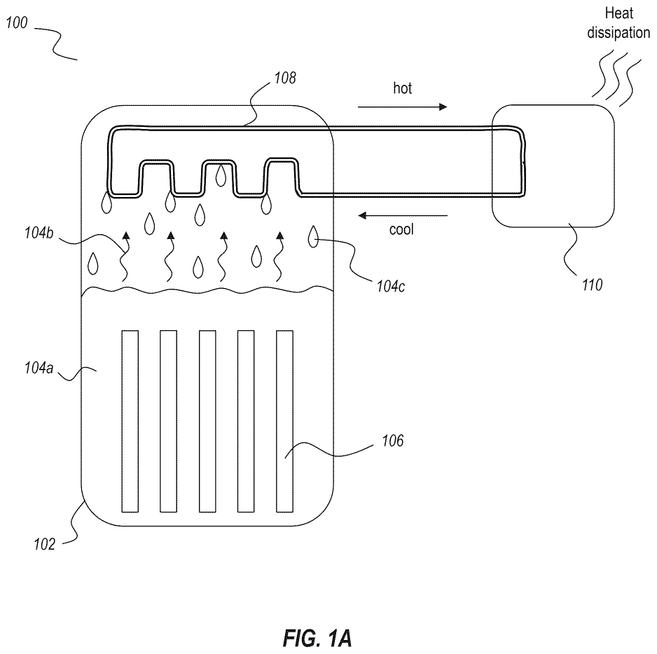

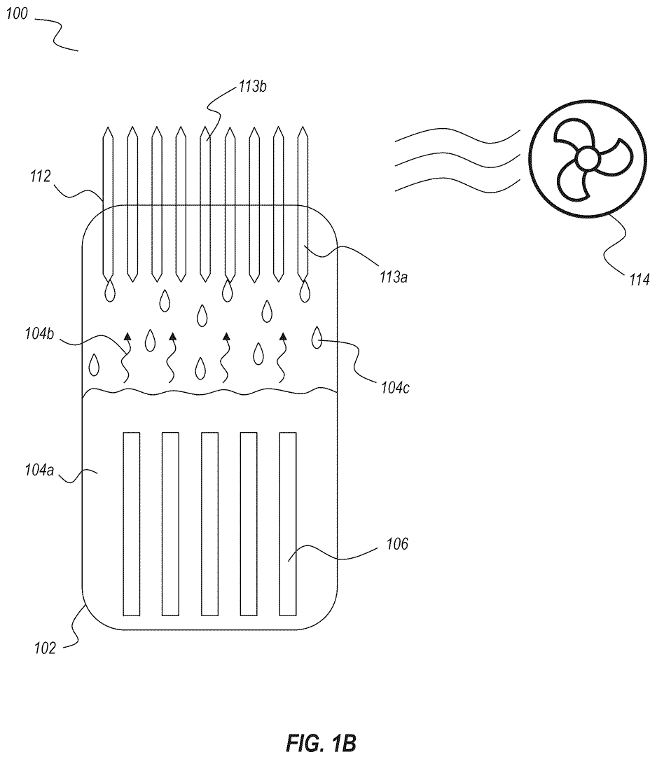

FIGS. 1A and 1B illustrate different configurations of an example two-phase immersion cooling system 100. As shown, the system 100 can include an immersion tank 102 configured to contain a liquid coolant 104a and to contain a component capable of generating heat (in this example, servers 106). As the servers 106 operate, the generated heat is transferred to the liquid coolant 104a, eventually bringing the liquid coolant 104a to its boiling point and forming vaporized coolant 104b. Boiling of the coolant enhances heat transfer due to the latent heat of vaporization (energy used during the liquid-to-vapor transition) of the coolant. The illustrated system 100 also includes a condenser configured to receive vaporized coolant 104b and to cool the vaporized coolant 104b to condensed form 104c where it can return to the immersion area as liquid coolant 104a.

In the example of FIG. 1A, the condenser is a cooling loop 108. The cooling loop 108 can include a secondary medium configured to remove heat from the vaporized coolant 104b and transfer heat to an external dissipation subsystem 110. The secondary medium can include water, glycol, a mineral oil, a silicone, a hydrocarbon, air, a refrigerant (e.g., when the condenser includes an active cooling system), or combination thereof, for example. The external dissipation subsystem 110 can include any subsystem capable of cooling the secondary medium. Examples include external thermal radiative elements (e.g., coils and/or radiative fins), a cooling tower, and/or an active cooling system (e.g., a chiller and/or other active system, such as those comprising a compressor and expansion valve).

In the example of FIG. 1B, the condenser is a set of thermal radiative elements 112 comprising first surfaces 113a that extend into the immersion tank 102 to contact vaporized coolant 104b and second surfaces 113b that extend away from the immersion tank 102 to dissipate heat gathered on the first surfaces 113a. The thermal radiative elements 112 can, for example, extend through a wall or other separation structure of the immersion tank 102 so that vaporized coolant 104b and coolant in condensed form 104c condensing on the first surfaces 113a does not pass outside the immersion tank 102. As shown, the system 100 can include a fan 114 configured to direct air over the second surfaces 113b of the thermal radiative elements 112 for heat removal. Other fluids may additionally or alternatively be utilized to promote conductive/convective heat transfer from the second surfaces 113b of the thermal radiative elements 112.

### Example Coolant Applications

Also disclosed herein is a method of using the compound CCC═C(F)CF as a coolant in a two-phase immersion cooling system. Such a system can be utilized to cool data centers (e.g., those housing cloud infrastructures), cryptocurrency mining operations, and/or high-performance or supercomputing systems (e.g., those used for scientific simulations, weather forecasting, etc.), for example. The disclosed cooling system can be used in conjunction with computing operations associated with various functions/services such as artificial intelligence, machine learning, and big data analytics, for example. In computing operations, the enhanced cooling enabled by the disclosed two-phase immersion cooling system can minimize the need for traditional air conditioning or chilled water systems and/or can allow for higher server packing and more compact equipment arrangements.

The disclosed cooling system can also have applications beyond computing operations. For example, a cooling system that uses the compound CCC═C(F)CF can be used for cooling other electronic equipment that generates heat, including electric vehicle batteries, electric grid and/or power supply electronics (e.g., converters, inverters, transformers, solar equipment), aerospace equipment, telecommunications equipment, and industrial equipment (e.g., machining tools, laser systems, robotics), for example.

### Working Examples

### 1. Synthesis of CCC═C(F)CF

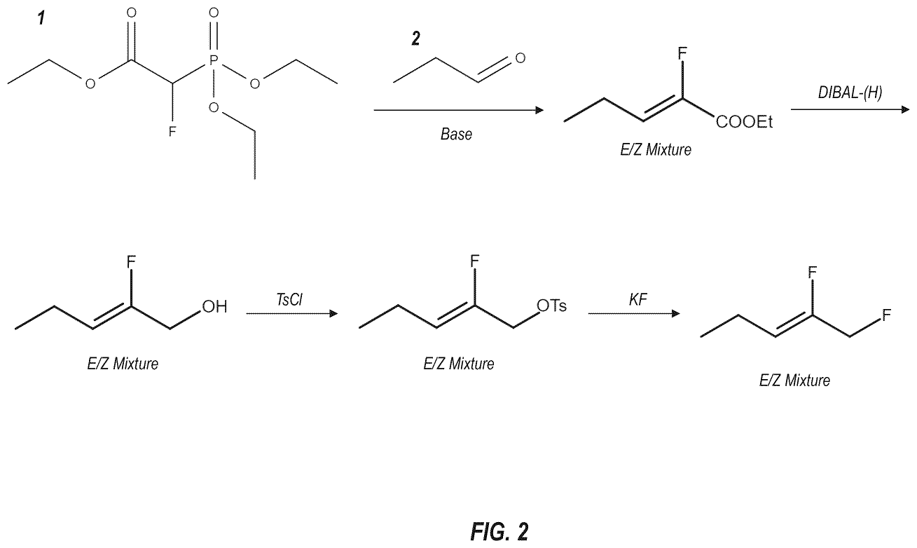

The compound 1,2-difluoropent-2-ene (i.e., compound CCC═C(F)CF) was synthesized according to the reaction scheme shown in FIG. 2, with reaction parameters and conditions shown in Table 1. Equivalents (eq.) are reported on a volume basis, and the reported volume ratios (V) refer to the volume ratio of solvent with respect to 1.0 equivalent.

TABLE 1
Reaction Parameters and Conditions

| Step | Reagents and Solvents | Conditions |
|---|---|---|
| 1 | Reagent 1 (1.0 eq) | −70° C. (2 h) |
| | Reagent 2 (1.2 eq) | 20° C. to 25° C. (1 h) |
| | LiHMDS (1.2 eq) | |
| | THF (10 V) | |
| 2 | E/Z Mixture from Step 1 (1.0 eq) | −30° C. (3 h) |
| | DIBAL-H (2.5 eq) | 30° C. to 35° C. (1 h) |
| | THF (3 V) | |
| 3 | E/Z Mixture from Step 2 (1.0 eq) | −10° C. (0.75 h) |
| | TsCl (1.2 eq) | |
| | Et₃N (1.4 eq) | |
| | DMAP (0.04 eq) | |
| | DCM (10 V) | |
| 4 | E/Z Mixture from Step 3 (1.0 eq) | 80° C. (5 h) |
| | KF (3.0 eq) | |
| | 18-Crown-6 (1.0 eq) | |
| | 1,2-dichlorobenzene (10 V) | |

In a first step, triethyl 2-fluoro-2-phosphonoacetate (Reagent 1) was reacted with propionaldehyde (Reagent 2) under basic conditions in lithium bis(trimethylsilyl)amide (LiHMDS) and tetrahydrofuran (THF), resulting in formation of an E/Z mixture of ethyl 2-fluoropent-2-enoate (only a single isomer is shown for ease of illustration).

In a second step, the E/Z mixture from step 1 is reacted with diisobutylaluminum hydride (DIBAL-H) to generate an E/Z mixture of 2-fluoropent-2-en-1-ol.

In a third step, the E/Z mixture from step 2 is reacted with toluenesulphonyl chloride (TsCl) to replace the hydroxyl group with a tosyloxy group.

In a fourth step, the E/Z mixture from step 3 is reacted with potassium fluoride (KF) to form an E/Z mixture of 1,2-difluoropent-2-ene.

### 2. Characterization of CCC═C(F)CF

Characterization testing was carried out to determine properties of the compound CCC═C(F)CF. In accordance with ASTM D1120, the boiling point of a pure isomer sample was measured as 84.6° C. and the boiling point of an E/Z mixture sample was measured as 82.6° C.

### Example Aspects

The following list of clauses represents a non-exhaustive list of example features disclosed herein. It will be understood that other combinations of features are also possible.

Clause 1. A composition comprising the compound CCC═C(F)CF.

Clause 2. The composition of clause 1, wherein the composition comprises the compound as one or both of the diastereomer forms: DRAWING (E-isomer), DRAWING (Z-isomer).

Clause 3. The composition of clause 2, wherein the composition comprises the compound as a pure isomer.

Clause 4. The composition of clause 2, wherein the composition comprises the compound as a diastereomeric mixture.

Clause 5. The composition of clause 4, wherein the diastereomeric mixture has an E:Z isomeric ratio of 9:1 to 1:9.

Clause 6. The composition of any one of clauses 1-5, wherein the composition omits per- and polyfluoroalkyl substances (PFAS).

Clause 7. A coolant composition formulated for two-phase immersion cooling, the coolant composition comprising the compound as in any one of clauses 1-6.

Clause 8. A two-phase immersion cooling system, comprising: the coolant composition of clause 7; an immersion tank configured to contain the dielectric coolant and to contain a component capable of generating heat; and a condenser configured to receive vaporized coolant and to condense the vaporized coolant back to liquid form.

Clause 9. The two-phase immersion cooling system of clause 8, wherein the condenser includes external components for dissipating heat to an environment external to the immersion tank.

Clause 10. The two-phase immersion cooling system of clause 9, wherein the condenser comprises a cooling loop that includes a secondary medium configured to remove heat from vaporized coolant and transfer heat to an external dissipation subsystem.

Clause 11. The two-phase immersion cooling system of clause 10, wherein the secondary medium comprises water, glycol, a mineral oil, a silicone, a hydrocarbon, air, a refrigerant, or combination thereof.

Clause 12. The two-phase immersion cooling system of clause 10 or clause 11, wherein the external dissipation subsystem comprises external thermal radiative elements, a cooling tower, and/or an active cooling system comprising a compressor and expansion valve.

Clause 13. The two-phase immersion cooling system of clause 12, wherein the external thermal radiative elements comprise coils and/or radiator fins.

Clause 14. The two-phase immersion cooling system of any one of clauses 8-13, wherein the condenser comprises a set of thermal radiative elements comprising first surfaces that extend into the immersion tank to contact vaporized coolant and second surfaces that extend away from the immersion tank to dissipate heat gathered on the first surfaces.

Clause 15. The two-phase immersion cooling system of clause 14, further comprising a fan configured to direct air over the second surfaces of the thermal radiative elements.

Clause 16. A method of cooling a piece of equipment, the method comprising: positioning the piece of equipment in an immersion tank with a coolant composition as in clause 7; and operating the piece of equipment, wherein operation of the piece of equipment generates heat that is transferred away from the piece of equipment by the coolant composition.

Clause 17. The method of clause 16, wherein operation of the piece of equipment generates heat sufficient to bring the coolant composition to its boiling point.

Clause 18. The method of clause 16 or clause 17, wherein the piece of equipment comprises a motherboard, central processing unit (CPU), graphics processing unit (GPU), memory module, solid-state drive (SSD), application-specific integrated circuit (ASIC), switch, router, network interface card (NIC), power supply unit (PSU), power distribution unit (PDU), inverter, transformer, rectifier, battery cell, battery management system (BMS), radio component, radar component, microcontroller, motor, actuator, power amplifier, or combination thereof.

Clause 19. The method of any one of clauses 16-18, wherein the method is used to cool a data center, cryptocurrency mining operation, and/or high-performance or supercomputing system

Clause 20. The method of any one of clauses 16-19, wherein the method is used to cool at least a portion of a system that operates to perform artificial intelligence, machine learning, and/or big data analytics.

Clause 21. The method of any one of clauses 16-20, carried out using a two-phase immersion cooling system of any one of clause 8-15.

### Additional Terms & Definitions

The embodiments disclosed herein should be understood as comprising/including disclosed components and may therefore include additional components not specifically described. For example, “a coolant comprising the compound CCC═C(F)CF” does not exclude the possibility of other components in the coolant.

Any feature positively disclosed herein may optionally be expressly omitted (essentially omitted or completely omitted, as defined herein) in the claims.

Optionally, the embodiments disclosed herein are essentially free or completely free of components that are not specifically described. That is, non-disclosed components may optionally be completely omitted or essentially omitted from the disclosed embodiments. For example, a coolant may essentially omit or completely omit other coolant compounds not specifically disclosed herein, including any coolant compound with a different formula.

An embodiment that “essentially omits” a component may include trace amounts and/or non-functional amounts of the component. For example, an “essentially omitted” component may be included in an amount no more than 1%, no more than 0.5%, no more than 0.1%, or no more than 0.01% by total weight of the relevant composition (e.g., by total weight of the coolant).

A composition that “completely omits” a component does not include a detectable amount of the component (i.e., does not include an amount above any inherent background signal associated with an appropriate testing instrument) when analyzed using standard compositional analysis techniques such as, for example, microscopy imaging techniques, chromatographic techniques (e.g., thin-layer chromatography (TLC), gas chromatography (GC), liquid chromatography (LC)), or spectroscopy techniques (e.g., Fourier transform infrared (FTIR) spectroscopy).

When the terms “about,” “approximately,” “substantially,” or the like are used in conjunction with a stated amount, value, or condition, it may be taken to mean an amount, value or condition that deviates by less than 10%, less than 5%, less than 1%, less than 0.1%, or less than 0.01% of the stated amount, value, or condition.

Any headings and subheadings used herein are for organizational purposes only and are not meant to be used to limit the scope of the description or the claims.

It will also be noted that, as used in this specification and the appended claims, the singular forms “a,” “an” and “the” do not exclude plural referents unless the context clearly dictates otherwise. Thus, for example, an embodiment referencing a singular referent may also include two or more such referents.

It will also be appreciated that embodiments described herein may also include properties and/or features described in one or more separate embodiments and are not necessarily limited strictly to the features expressly described for that particular embodiment. That is, one or more features of a given embodiment can be combined with and/or incorporated into other embodiments of the present disclosure. Accordingly, any of the originally presented claims can be amended to incorporate elements of any other claim(s), regardless of the specific dependency structure of the originally presented claims, except where such features are clearly mutually exclusive. Thus, although an originally presented claim may have a specific claim dependency, the claim will be understood, for purposes of supporting disclosure, as though it depends from “any preceding claim,” except those where mutually exclusive features clearly dictate otherwise.

1. A composition comprising the compound CCC═C(F)CF.

2. The composition of claim 1, wherein the composition comprises the compound as one or both of the diastereomer forms:

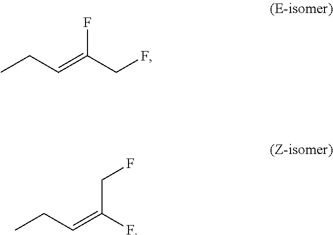

3. The composition of claim 2, wherein the composition comprises the compound as a pure isomer.

4. The composition of claim 2, wherein the composition comprises the compound as a diastereomeric mixture.

5. The composition of claim 4, wherein the diastereomeric mixture has an E:Z isomeric ratio of 9:1 to 1:9.

6. The composition of claim 1, wherein the composition omits per- and polyfluoroalkyl substances (PFAS).

7. A coolant composition formulated for two-phase immersion cooling, the coolant composition comprising the compound as in claim 1.

8. A two-phase immersion cooling system, comprising:
the coolant composition of claim 7;
an immersion tank configured to contain the dielectric coolant and to contain a component capable of generating heat; and
a condenser configured to receive vaporized coolant and to condense the vaporized coolant back to liquid form.

9. The two-phase immersion cooling system of claim 8, wherein the condenser includes external components for dissipating heat to an environment external to the immersion tank.

10. The two-phase immersion cooling system of claim 9, wherein the condenser comprises a cooling loop that includes a secondary medium configured to remove heat from vaporized coolant and transfer heat to an external dissipation subsystem.

11. The two-phase immersion cooling system of claim 10, wherein the secondary medium comprises water, glycol, a mineral oil, a silicone, a hydrocarbon, air, a refrigerant, or combination thereof.

12. The two-phase immersion cooling system of claim 10, wherein the external dissipation subsystem comprises external thermal radiative elements, a cooling tower, and/or an active cooling system comprising a compressor and expansion valve.

13. The two-phase immersion cooling system of claim 12, wherein the external thermal radiative elements comprise coils and/or radiator fins.

14. The two-phase immersion cooling system of claim 8, wherein the condenser comprises a set of thermal radiative elements comprising first surfaces that extend into the immersion tank to contact vaporized coolant and second surfaces that extend away from the immersion tank to dissipate heat gathered on the first surfaces.

15. The two-phase immersion cooling system of claim 14, further comprising a fan configured to direct air over the second surfaces of the thermal radiative elements.

16. A method of cooling a piece of equipment, the method comprising:
positioning the piece of equipment in an immersion tank with a coolant composition as in claim 7; and
operating the piece of equipment,
wherein operation of the piece of equipment generates heat that is transferred away from the piece of equipment by the coolant composition.

17. The method of claim 16, wherein operation of the piece of equipment generates heat sufficient to bring the coolant composition to its boiling point.

18. The method of claim 16, wherein the piece of equipment comprises a motherboard, central processing unit (CPU), graphics processing unit (GPU), memory module, solid-state drive (SSD), application-specific integrated circuit (ASIC), switch, router, network interface card (NIC), power supply unit (PSU), power distribution unit (PDU), inverter, transformer, rectifier, battery cell, battery management system (BMS), radio component, radar component, microcontroller, motor, actuator, power amplifier, or combination thereof.

19. The method of claim 16, wherein the method is used to cool a data center, cryptocurrency mining operation, and/or high-performance or supercomputing system.

20. The method of claim 16, wherein the method is used to cool at least a portion of a system that operates to perform artificial intelligence, machine learning, and/or big data analytics.
